(19) United States
(12) Patent Application Publication
(10) Pub. No.: US 2009/0283845 A1
(43) Pub. Date: Nov. 19, 2009

(54) SENSING APPARATUS WITH PACKAGING MATERIAL AS SENSING PROTECTION LAYER AND METHOD OF MANUFACTURING THE SAME

(76) Inventor: Bruce C.S. CHOU, Hsin Chu City (TW)

Correspondence Address: Muncy, Geissler, Olds & Lowe, PLLC, P.O. BOX 1364, FAIRFAX, VA, 22038-1364, US

(21) Appl. No.: 12/463,722

(22) Filed: May 11, 2009

(30) Foreign Application Priority Data
May 19, 2008 (TW) 097118321

(51) Int. Cl. H01L 31/0203; H01L 21/56; H01L 23/31; H01L 27/146; H01L 31/18

(52) U.S. Cl. 257/417; 257/427; 257/433; 257/467; 438/51; 438/55; 438/66; 257/E21.502; 257/E23.123; 257/E27.13; 257/E31.117

(57) ABSTRACT

A sensing apparatus includes a holding substrate, a sensing chip and a protection layer. The sensing chip is mounted on the holding substrate and electrically connected to the holding substrate. The sensing chip has a sensing region and a non-sensing region other than the sensing region. The sensing region senses image data of an object and thus generates a sensed signal outputted to the holding substrate. The protection layer is formed by a packaging material and is simultaneously processed and integrally formed to cover the sensing region and the non-sensing region of the sensing chip and the holding substrate. The protection layer has an exposed upper surface, which has one portion serving as a sensing surface in contact with the object. The entire protection layer is composed of the same material.

This application claims priority of No. 097118321 filed in Taiwan R.O.C. on May 19, 2008 under 35 USC 119, the entire content of which is hereby incorporated by reference.

### BACKGROUND OF THE INVENTION

1. Field of the Invention

The invention relates to a sensing apparatus having a protection layer and a method of manufacturing the same, and more particularly to an apparatus for measuring a fingerprint or an image of a finger-associated biometrics message.

2. Related Art

A conventional fingerprint sensing apparatus formed by a non-optical sensing chip cannot be applied to various electronic products until it is packaged for standard production flow. However, the conventional fingerprint sensing apparatus has a specific feature with that an exposed chip surface has to be provided to contact with a finger and thus to sense an image of the finger. Therefore, a special molding tool and a polymer material layer have to be used to protect the sensing surface of the sensing chip during the packaging process. In addition, the two ends or the periphery of a wire-bonding area of the packaged sensing chip bulges higher than the sensing surface in the middle portion after the molding compound is formed.

Based on the above-mentioned reasons, the conventional fingerprint sensing apparatus has the high package cost, and needs to use a special machine. In addition, because the external surface of the fingerprint sensing chip has to be exposed, its abilities of withstanding the electrostatic discharge damage and force impact from the approaching fingertip are limited so as to cause product reliability issues.

Therefor, it is an important subject of the invention to provide a fingerprint sensing apparatus capable of overcoming the above-mentioned problems.

### SUMMARY OF THE INVENTION

It is therefore an object of the invention to provide a sensing apparatus having a protection layer and a method of manufacturing the same, in which the protection layer is integrally and simultaneously formed to cover and thus to protect a sensing chip.

To achieve the above-identified object, the invention provides a sensing apparatus including a holding substrate, a sensing chip and a protection layer. The sensing chip is mounted on the holding substrate and electrically connected to the holding substrate. The sensing chip has a sensing region and a non-sensing region other than the sensing region. The sensing region is for sensing image data of an object and thus generating a sensed signal outputted to the holding substrate. The protection layer is simultaneously processed and integrally formed to cover the sensing region and the non-sensing region of the sensing chip and the holding substrate. The protection layer has an exposed upper surface, which has one portion serving as a sensing surface in contact with the object. The entire protection layer is composed of the same material.

The invention also provides a method of manufacturing a sensing apparatus. The method includes the steps of: providing a holding substrate; mounting a sensing chip on the holding substrate and electrically connecting the sensing chip to the holding substrate, wherein the sensing chip has a sensing region and a non-sensing region other than the sensing region, and the sensing region senses image data of an object and thus generates a sensed signal outputted to the holding substrate; and simultaneously processing and integrally forming a protection layer to cover the sensing region and the non-sensing region of the sensing chip and the holding substrate, wherein the protection layer has an exposed upper surface, which has one portion serving as a sensing surface in contact with the object, and the entire protection layer is composed of the same material.

According to the sensing apparatus having the protection layer and the method of manufacturing the same, the protection layer, which is used in the packaging process, may be provided to protect the sensing chip. In addition, a substantially flat surface may be easily manufactured to serve as the sensing surface during the packaging process. When the sensing chip senses the fingerprint of a finger sweeping thereacross, the finger will not be restricted by a non-flat surface. Alternatively, the protection layer may also have the non-flat surface. In this case, the packaging material may also be used to protect the sensing chip, and the required package cost may also be greatly lowered.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a schematically cross-sectional view showing a sensing apparatus according to a first embodiment of the invention.

FIG. 2 is a schematic illustration showing the sensing apparatus according to the first embodiment of the invention.

FIG. 3 is a schematically cross-sectional view showing a sensing apparatus according to a second embodiment of the invention.

FIGS. 4 to 6 are schematic illustrations showing structures corresponding to steps of a method of manufacturing the sensing apparatus according to the first embodiment of the invention.

### DETAILED DESCRIPTION OF THE INVENTION

The present invention will be apparent from the following detailed description, which proceeds with reference to the accompanying drawings, wherein the same references relate to the same elements.

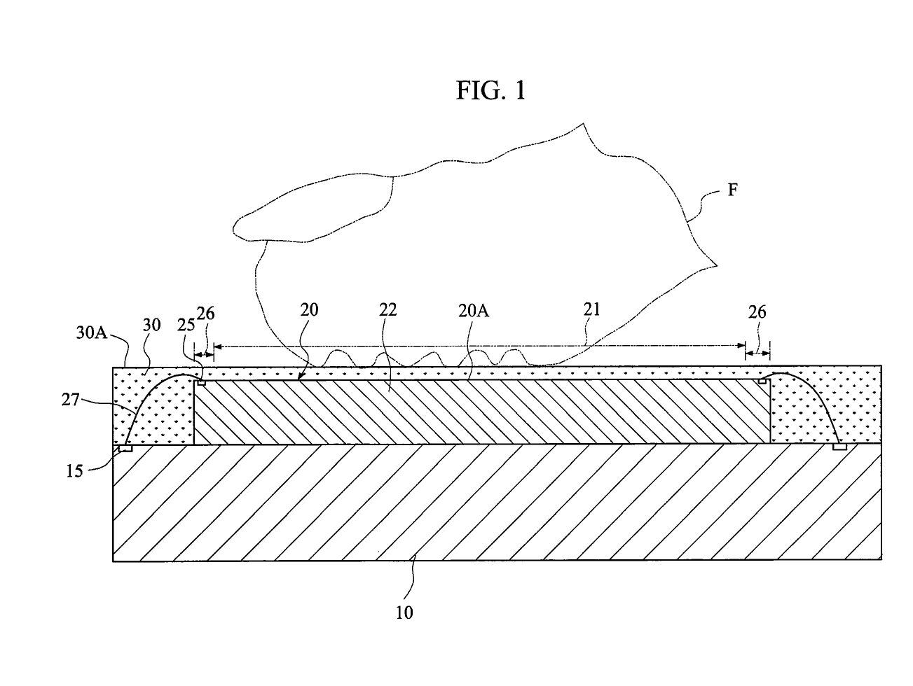

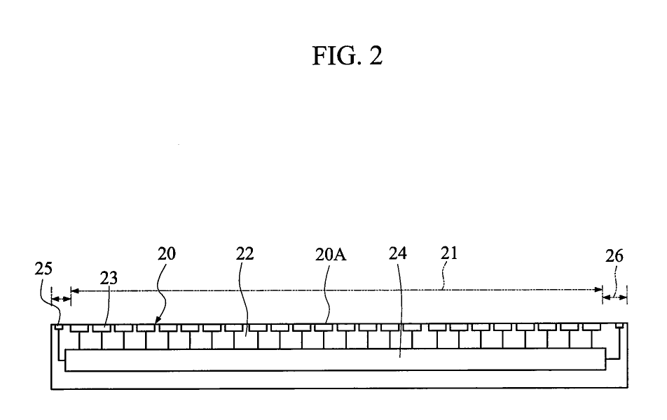

FIG. 1 is a schematically cross-sectional view showing a sensing apparatus according to a first embodiment of the invention. FIG. 2 is a schematic illustration showing the sensing apparatus according to the first embodiment of the invention. Referring to FIGS. 1 and 2, the sensing apparatus of this embodiment includes a holding substrate 10, a sensing chip 20 and a protection layer 30.

The holding substrate 10 may be a package substrate, such as a lead frame, a printed circuit board, a ball grid array (BGA) substrate, or the like.

The sensing chip 20 is mounted on the holding substrate 10 and electrically connected to the holding substrate 10. In this embodiment, bonding pads 25 of the sensing chip 20 are electrically connected to bonding pads 15 of the holding substrate 10 via bonding wires 27, respectively. In other embodiments, the electrical connection may also be achieved by other methods.

The sensing chip 20 has a sensing region 21 and a non-sensing region 26 other than the sensing region 21. The sensing region 21 senses the image data (e.g., the fingerprint) of an object (e.g., a finger F) and thus generates a sensed signal to be outputted to the holding substrate 10.

The protection layer 30 is simultaneously processed and integrally formed to cover the sensing region 21 and the non-sensing region 26 of the sensing chip 20 and the holding substrate 10. The protection layer 30 has an exposed upper surface 30A, which has one portion serving as a sensing surface in contact with the finger F. Because the protection layer 30 is integrally formed, the entire protection layer 30 is composed of the same material.

In this embodiment, the upper surface 30A is flat, and the area of the upper surface 30A of the protection layer 30 is greater than the area of an upper surface 20A of the sensing chip 20. In other embodiments, the area of the upper surface 30A of the protection layer 30 may also be equal to the area of the upper surface 20A of the sensing chip 20.

In order to maintain the sensing capability, a distance from the upper surface 30A of the protection layer 30 to the upper surface 20A of the sensing chip 20 is substantially shorter than 200 microns.

The sensing apparatus of this embodiment is different from the conventional optical sensing apparatus, which needs an optical module. The sensing chip 20 briefly includes a chip substrate 22, a plurality of sensing members 23 and a signal processing circuit 24. The chip substrate 22 is usually a semiconductor substrate. The sensing members 23 are formed on the chip substrate 22 and arranged in an array corresponding to the sensing region 21. Each sensing member 23 is a capacitive sensing member, an electric field sensing member, a radio frequency (RF) sensing member, a pressure sensing member, a magnetic field sensing member, an ultrasonic sensing member, an infrared sensing member or a thermal sensing member. The sensed image data corresponds to textures of the finger skin in this embodiment, and the subcutaneous image, such as the fingerprint or vein/blood vessel image of the dermal layer in another embodiment. This array may be a rectangular array so that the sensing members 23 sense the fingerprint of the finger F sliding thereacross, or the fingerprint of the finger F, which is stationary and placed thereon. The signal processing circuit 24 formed in the chip substrate 22 and electrically connected to the sensing members 23 processes a plurality of original signals coming from the sensing members 23.

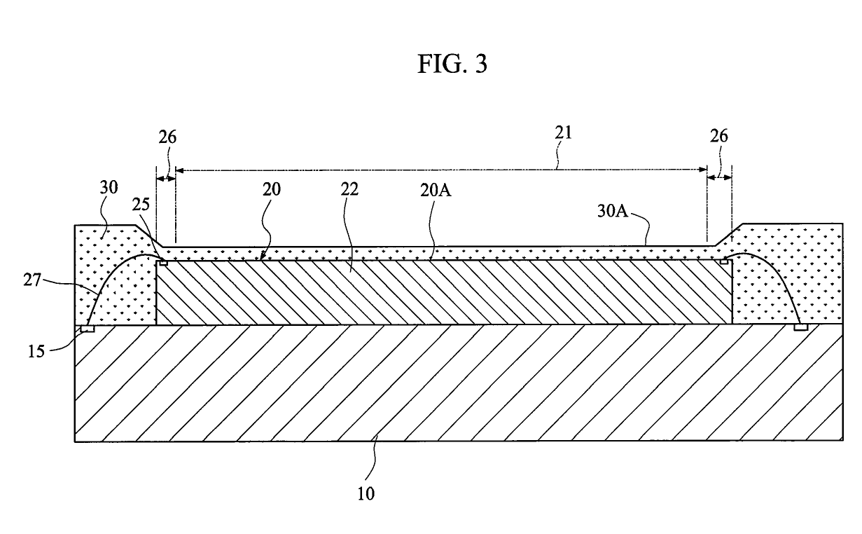

FIG. 3 is a schematically cross-sectional view showing a sensing apparatus according to a second embodiment of the invention. As shown in FIG. 3, this embodiment is similar to the first embodiment except that the upper surface 30A is not flat, but the protection layer 30 above the sensing region 21 is located at a level lower than the protection layer 30 above the non-sensing region 26.

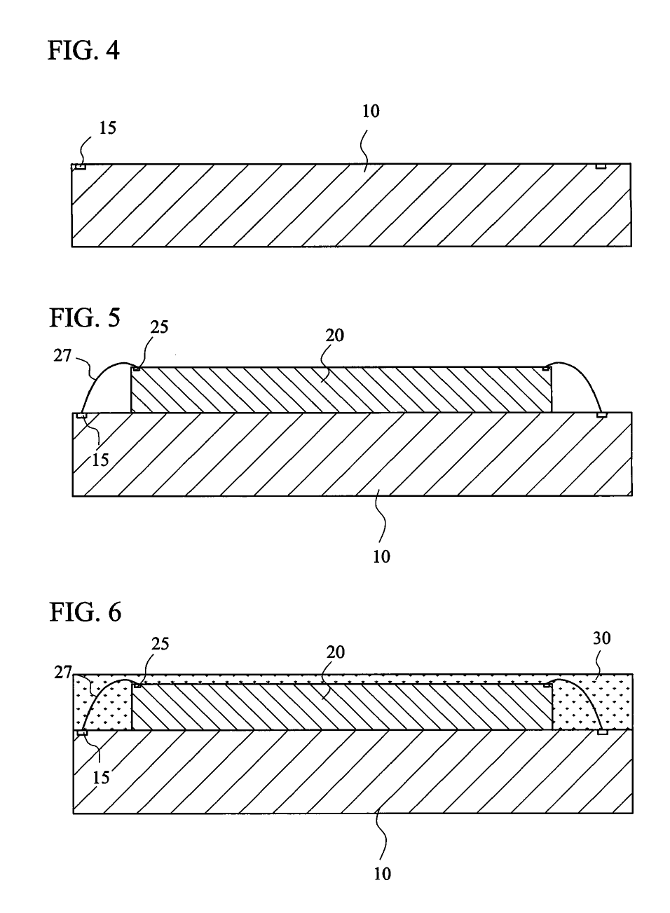

FIGS. 4 to 6 are schematic illustrations showing structures corresponding to steps of a method of manufacturing the sensing apparatus according to the first embodiment of the invention.

First, as shown in FIG. 4, the holding substrate 10 is provided.

Next, as shown in FIGS. 5 and 1, the sensing chip 20 is mounted on and electrically connected to the holding substrate 10. The sensing chip 20 has the sensing region 21 and the non-sensing region 26 other than the sensing region 21. The sensing region 21 is for sensing the fingerprint of the finger F and thus generating the sensed signal outputted to the holding substrate 10.

Then, as shown in FIGS. 6 and 1, the protection layer 30 is integrally formed to cover the sensing region 21 and the non-sensing region 26 of the sensing chip 20 and the holding substrate 10. The protection layer 30 has the exposed upper surface 30A, which has one portion serving as the sensing surface to be in contact with the finger F. The entire protection layer 30 is composed of the same material.

Other features have been described in FIGS. 1 and 2, so detailed descriptions thereof will be omitted.

According to the sensing apparatus having the protection layer and the method of manufacturing the same, the protection layer, which is used in the packaging process, may be provided to protect the sensing chip. In addition, a substantially flat surface may be easily manufactured to serve as the sensing surface during the packaging process. When the sensing chip senses the fingerprint of the finger sliding thereacross, the finger will not be restricted by a non-flat surface. Alternatively, the protection layer may also have the non-flat surface. In this case, the packaging material may also be used to protect the sensing chip, and the required package cost may also be greatly lowered.

While the invention has been described by way of examples and in terms of preferred embodiments, it is to be understood that the invention is not limited thereto. To the contrary, it is intended to cover various modifications. Therefore, the scope of the appended claims should be accorded the broadest interpretation so as to encompass all such modifications.

What is claimed is:

1. A sensing apparatus, comprising:
a holding substrate;
a sensing chip mounted on the holding substrate and electrically connected to the holding substrate, wherein the sensing chip has a sensing region and a non-sensing region other than the sensing region, the sensing region is for sensing image data of an object and thus generating a sensed signal outputted to the holding substrate; and
a protection layer, which is simultaneously processed and integrally formed to cover the sensing region and the non-sensing region of the sensing chip and the holding substrate, wherein the protection layer has an exposed upper surface, which has one portion serving as a sensing surface in contact with the object, and the entire protection layer is composed of the same material.

2. The sensing apparatus according to claim 1, wherein an area of the upper surface of the protection layer is larger than an area of an upper surface of the sensing chip.

3. The sensing apparatus according to claim 1, wherein the holding substrate is a lead frame, a printed circuit board or a ball grid array (BGA) substrate.

4. The sensing apparatus according to claim 1, wherein a distance from the upper surface of the protection layer to an upper surface of the sensing chip is substantially smaller than 200 microns.

5. The sensing apparatus according to claim 1, wherein the sensing chip comprises:
a chip substrate;
a plurality of sensing members formed on the chip substrate, wherein the sensing members are arranged in an array corresponding to the sensing region; and
a processing circuit, formed in the chip substrate and electrically connected to the sensing members, for processing a plurality of original signals coming form the sensing members.

6. The sensing apparatus according to claim 5, wherein the array is a rectangular array, and the sensing members sense the image data of the object sweeping across the array.

7. The sensing apparatus according to claim 5, wherein the array is a rectangular array, and the sensing members sense the image data of the object, which is stationary and placed on the array.

8. The sensing apparatus according to claim 5, wherein each of the sensing members is a capacitive sensing member, an electric field sensing member, a radio frequency (RF) sensing member, a pressure sensing member, a magnetic field sensing member, an ultrasonic sensing member, an infrared sensing member or a thermal sensing member.

9. The sensing apparatus according to claim 1, wherein bonding pads of the sensing chip are electrically connected to bonding pads of the holding substrate via wires, respectively.

10. The sensing apparatus according to claim 1, wherein the upper surface is flat.

11. The sensing apparatus according to claim 1, wherein the protection layer above the sensing region is located at a level lower than the protection layer above the non-sensing region.

12. A method of manufacturing a sensing apparatus, the method comprising the steps of:
providing a holding substrate;
mounting a sensing chip on the holding substrate and electrically connecting the sensing chip to the holding substrate, wherein the sensing chip has a sensing region and a non-sensing region other than the sensing region, and the sensing region senses image data of an object and thus generates a sensed signal outputted to the holding substrate; and
simultaneously processing and integrally forming a protection layer to cover the sensing region and the non-sensing region of the sensing chip and the holding substrate, wherein the protection layer has an exposed upper surface, which has one portion serving as a sensing surface in contact with the object, and the entire protection layer is composed of the same material.

13. The method according to claim 12, wherein an area of the upper surface of the protection layer is greater than an area of an upper surface of the sensing chip.

14. The method according to claim 12, wherein a distance from the upper surface the protection layer to an upper surface of the sensing chip is substantially smaller than 200 microns.

15. The method according to claim 12, wherein the sensing chip comprises:
a chip substrate;
a plurality of sensing members formed on the chip substrate, the sensing members being arranged in an array corresponding to the sensing region; and
a processing circuit, formed inn the chip substrate and electrically connected to the sensing members, for processing a plurality of original signals coming from the sensing members.

16. The method according to claim 12, wherein bonding pads of the sensing chip are electrically connected to bonding pads of the holding substrate via wires, respectively.

17. The method according to claim 12, wherein the upper surface is flat.

18. The method according to claim 12, wherein the protection layer above the sensing region is located at a level lower than the protection layer above the non-sensing region.
